(19) United States
(12) Patent Application Publication
(10) Pub. No.: US 2023/0035764 A1
(43) Pub. Date: Feb. 2, 2023

(54) LASER TREATMENT DEVICE AND LASER TREATMENT METHOD

(71) Applicant: Aledia, Echirolles (FR)

(72) Inventors: Tiphaine Dupont, Grenoble (FR); Mehdi Daanoune, Voreppe (FR); Olivier Jeannin, Grenoble (FR); Ivan-Christophe Robin, Grenoble (FR); Florian Dupont, Grenoble (FR)

(73) Assignee: Aledia, Echirolles (FR)

(21) Appl. No.: 17/788,259

(22) PCT Filed: Dec. 18, 2020
(86) PCT No.: PCT/EP2020/087242

§ 371 Date: Jun. 22, 2022

(30) Foreign Application Priority Data
Dec. 26, 2019 (FR) 1915606

(51) Int. Cl. B23K 26/18; B23K 26/322

(52) U.S. Cl. CPC B23K 26/18; B23K 26/322; B23K 2101/42

(57) ABSTRACT

A device configured for a laser treatment including a substrate transparent for the laser and objects, each object being bonded to the substrate via a photonic crystal.

The present patent application claims the priority benefit of French patent application FR19/15606 which is herein incorporated by reference.

### TECHNICAL BACKGROUND

The present disclosure generally concerns laser treatment devices and methods of laser treatment of such a device.

### PRIOR ART

For certain applications, it is desirable to be able to perform a laser treatment of an object present on a support substantially transparent to the laser, through the support. An example of application concerns the detaching of an object, for example, an electronic circuit, bonded to the support. For this purpose, a layer which is absorbing for the laser is interposed between the object to be detached and the support, and the laser beam is focused onto this absorbing layer, the ablation of the absorbing layer causing the detaching of the object from the support. The absorbing layer for example corresponds to a metal layer, particularly a gold layer.

In the case where the object is an electronic circuit, it may be desirable for the support to correspond to the substrate on which the electronic circuit is formed to avoid the transfer of the electronic circuit onto the support. In this case, the absorbing layer corresponds to a layer which is monolithically formed with the layers of the electronic circuit.

A disadvantage is that it may be difficult to form an absorbing layer having the desired absorption properties. This may in particular be the case when the object is at least partly formed by the deposition of layers by epitaxy on the absorbing layer. Indeed, it is then generally not possible to use an absorption layer which is metallic. It is then necessary to increase the power of the laser used to cause the removal of the absorbing layer. It may then be difficult to prevent the deterioration of the regions close to the absorbing layer, particularly those forming part of the object to be detached. This may further be the case when the thickness of the absorbing layer is limited, particularly for cost reasons or for technological feasibility reasons.

### SUMMARY OF THE INVENTION

Thus, an object of an embodiment is to at least partly overcome the disadvantages of the previously-described laser treatment devices and the previously-described laser treatment methods using such devices.

An object of an embodiment is for the laser beam to be focused onto a region to be treated of the device through a portion of the device.

Another object of an embodiment is for the areas close to the region to be treated not to be damaged by the treatment.

Another object of an embodiment is for the device manufacturing method not to comprise a step of transfer of one element onto another.

Another object of an embodiment is for the method of manufacturing the device to comprise epitaxial deposition steps.

Another object of an embodiment is for the thickness of the absorbing layer to be decreased.

An embodiment provides a device configured for a laser treatment, comprising a substrate transparent for the laser and objects, each object being bonded to the substrate via a photonic crystal.

According to an embodiment, the photonic crystal is a two-dimensional photonic crystal.

According to an embodiment, the photonic crystal comprises a base layer made of a first material and a grating of pillars made of a second material different from the first material, each pillar extending in the base layer across a portion at least of the thickness of the base layer.

According to an embodiment, the first material has an absorption coefficient for the laser smaller than 1.

According to an embodiment, the second material has an absorption coefficient for the laser smaller than 1.

According to an embodiment, the substrate is formed of said second material.

According to an embodiment, the second material has an absorption coefficient for the laser in the range from 1 to 10.

According to an embodiment, the substrate comprises first and second opposite surfaces, the laser being intended to cross the substrate from the first surface to the second surface, the photonic crystal covering the second surface.

According to an embodiment, the device further comprises a layer absorbing for the laser between the objects and the substrate.

According to an embodiment, the device further comprises at least one layer transparent for the laser, interposed between the photonic crystal and the layer absorbing for the laser.

According to an embodiment, the substrate is semiconductor.

According to an embodiment, the substrate is made of silicon, of germanium, or of a mixture or an alloy of at least two of these compounds.

According to an embodiment, the object comprises an electronic circuit.

According to an embodiment, the object comprises at least one optoelectronic component having a three-dimensional semiconductor element covered with an active layer, the three-dimensional semiconductor element comprising a base in contact with at least one of the pillars.

According to an embodiment, the second material is a nitride, a carbide, or a boride of a transition metal from column IV, V, or VI of the periodic table of elements or a combination of these compounds or the second material is aluminum nitride, aluminum oxide, boron, boron nitride, titanium, titanium nitride, tantalum, tantalum nitride, hafnium, hafnium nitride, niobium, niobium nitride, zirconium, zirconium borate, zirconium nitride, silicon carbide, tantalum carbonitride, magnesium nitride, or a mixture of at least two of these compounds.

An embodiment also provides a method of manufacturing a device comprising a substrate transparent for the laser and objects, each object being bonded to the substrate via a photonic crystal, the method comprising the forming of the photonic crystal and the forming of the object.

According to an embodiment, the method comprises the forming of the photonic crystal on the substrate and the forming of the object on the photonic crystal comprising steps of deposition and/or of growth of layers on the photonic crystal.

An embodiment also provides a method of laser treatment of a device comprising a substrate transparent for the laser and objects, each object being bonded to the substrate via a photonic crystal, the method comprising exposing the photonic crystal to the laser beam through the substrate.

According to an embodiment, the method comprises the bonding of the object to a support, the object being still coupled to the substrate and the destruction of a region comprising the photonic crystal or adjacent to the photonic crystal by the laser.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 illustrates an embodiment of a system of laser treatment of a device comprising an absorbing region;

FIG. 2 is an enlarged view of an embodiment of the absorbing region of the device of FIG. 1;

FIG. 3 is an enlarged view of another embodiment of the absorbing region of the device of FIG. 1;

FIG. 4 is an enlarged view of another embodiment of the absorbing region of the device of FIG. 1;

FIG. 5 shows an arrangement of the pillars of the photonic crystal layer of the absorbing region of the device of FIG. 1;

FIG. 6 shows another arrangement of the pillars of the photonic crystal layer of the absorbing region of the device of FIG. 1;

FIG. 7 is a partial simplified enlarged view of another embodiment of the absorbing region of the device of FIG. 1;

FIG. 8 is partial simplified top view with a cross-section of the device shown in FIG. 7;

FIG. 9 is a partial simplified cross-section view of an embodiment of an optoelectronic component of the device of FIG. 1;

FIG. 10 is a partial simplified cross-section view of another embodiment of an optoelectronic component of the device of FIG. 1;

FIG. 11 shows a curve of the variation of the absorption of the absorbing region of the device of FIG. 1 according to the ratio of the pitches of the pillars of the photonic crystal to the wavelength of the incident laser;

FIG. 12 shows a grayscale map of the absorption of the absorbing region of the device of FIG. 1 according to the pillar filling factor and to the ratio of the pitch of the pillars of the photonic crystal to the wavelength of the incident laser;

FIG. 13 shows another grayscale map of the absorption of the absorbing region of the device of FIG. 1 according to the pillar filling factor and to the ratio of the pitch of the pillars of the photonic crystal to the wavelength of the incident laser;

FIG. 14 shows a curve of the variation of the absorption of the absorbing region of the device of FIG. 1 according to the height of the pillars of the photonic crystal layer for first values of the pillar filling factor and to the ratio of the pitch of the pillars of the photonic crystal to the wavelength of the incident laser;

FIG. 15 shows a curve of the variation of the absorption of the absorbing region of the device of FIG. 1 according to the height of the pillars of the photonic crystal layer for second values of the pillar filling factor and to the ratio of the pitch of the pillars of the photonic crystal to the wavelength of the incident laser;

FIG. 16 shows the structure obtained at a step of an embodiment of a method of manufacturing the device of FIG. 1;

FIG. 17 shows the structure obtained at another step of the manufacturing method;

FIG. 18 shows the structure obtained at another step of the manufacturing method;

FIG. 19 shows the structure obtained at another step of the manufacturing method;

FIG. 20 shows the structure obtained at another step of the manufacturing method;

FIG. 21 shows the structure obtained at another step of the manufacturing method;

FIG. 22 shows the structure obtained at another step of the manufacturing method;

FIG. 23 shows the structure obtained at a step of an embodiment of a method of laser treatment implementing the device of FIG. 1;

FIG. 24 shows the structure obtained at another step of the laser treatment method;

FIG. 25 shows the structure obtained at another step of the laser treatment method;

FIG. 26 shows the structure obtained at another step of the laser treatment method;

FIG. 27 shows another arrangement of the pillars of the photonic crystal layer of the device of FIG. 1;

FIG. 28 is a drawing similar to FIG. 7 obtained with the arrangement shown in FIG. 27;

FIG. 29 shows a grayscale map of the density of energy in the photonic crystal layer according to the arrangement shown in FIG. 27; and

FIG. 30 shows another arrangement of the pillars of the photonic crystal layer of the device of FIG. 1.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, laser sources are well known by those skilled in the art and are not detailed hereafter.

In the rest of the disclosure, when reference is made to terms qualifying absolute positions, such as terms “front”, “rear”, “top”, “bottom”, “left”, “right”, etc., or relative positions, such as terms “above”, “under”, “upper”, “lower”, etc., unless specified otherwise, it is referred to the orientation of the drawings. Unless specified otherwise, the expressions “around”, “approximately”, “substantially” and “in the order of” signify within 10%, and preferably within 5%. Further, it is here considered that the terms “insulating” and “conductive” respectively signify “electrically insulating” and “electrically conductive”.

In the rest of the disclosure, the inner transmittance of a layer corresponds to the ratio of the intensity of the radiation coming out of the layer to the intensity of the radiation entering the layer, the rays of the incoming radiation being perpendicular to the layer. The absorption of the layer is equal to the difference between 1 and the inner transmittance. In the rest of the disclosure, a layer or a film is said to be transparent to a radiation when the absorption of the radiation through the layer or the film is smaller than 60%. In the rest of the disclosure, a layer or a film is said to be absorbing to a radiation when the absorption of the radiation through the layer or the film is greater than 60%. In the rest of the disclosure, it is considered that a laser corresponds to a monochromatic radiation. In practice, the laser may have a narrow wavelength range centered on a central wavelength, called wavelength of the laser. In the rest of the disclosure, the refraction index of a material corresponds to the refraction index of the material at the wavelength of the laser used for the laser treatment. Call absorption coefficient k the imaginary part of the optical index of the concerned material. It is coupled to the linear absorption a of the material according to relation α=4π/λ.

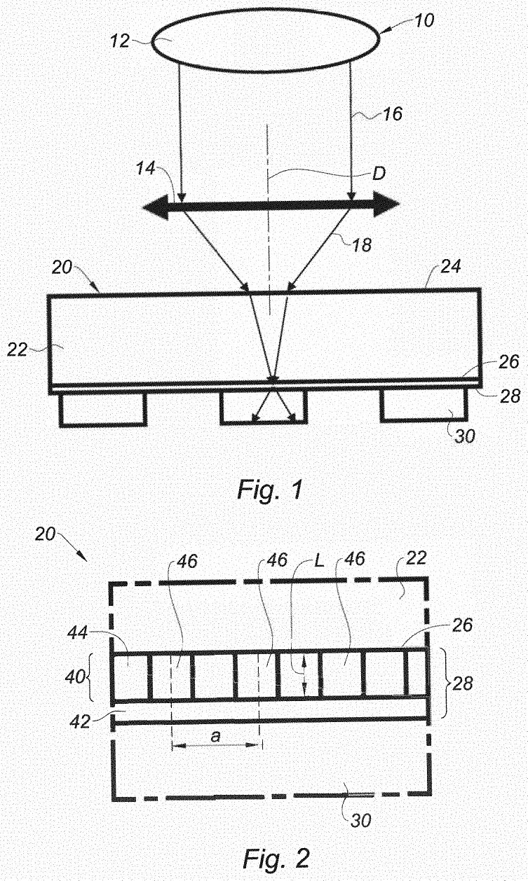

FIG. 1 is a partial simplified cross-section view of an embodiment of a treatment system 10 of a device 20.

Treatment system 10 comprises a laser source 12 and an optical focusing device 14 having an optical axis D. Source 12 is adapted to supplying an incident laser beam 16 to focusing device 14, which supplies a converging laser beam 18. Optical focusing device 14 may comprise one optical component, two optical components, or more than two optical components, an optical component for example corresponding to a lens. Preferably, incident laser beam 16 is substantially collimated along the optical axis D of optical device 14.

Device 20 comprises a substrate 22 comprising two opposite surfaces 24, 26. Laser beam 18 penetrates into substrate 22 through surface 24. According to an embodiment, surfaces 24 and 26 are parallel. According to an embodiment, surfaces 24 and 26 are planar. According to an embodiment, the thickness of substrate 22 is in the range from 50 μm to 3 mm. According to an embodiment, a layer of antireflection for the laser, not shown, is provided on surface 24 of substrate 22. Substrate 22 may have a monolayer structure or a multilayer structure. According to an embodiment, substrate 22 is made of a semiconductor material. The semiconductor material may be silicon, germanium, or a mixture of at least two of these compounds. Preferably, substrate 22 is made of silicon, more preferably of single-crystal silicon. According to another embodiment, substrate 22 is at least partly made of a non-semiconductor material, for example, an insulating material, particularly sapphire, or a conductive material.

Device 20 comprises an absorbing region 28 on surface 26 and at least one object 30 in contact with absorbing region 28 and bonded to the absorbing region on the side of absorbing region 28 opposite to substrate 22 and which is desired to be detached from substrate 22. As an example, a plurality of objects 30 are shown in FIG. 1 as bonded to the absorbing region. Object 30 may comprise an electronic circuit, for example, a circuit comprising light-emitting diodes or a circuit comprising transistors, particularly MOS transistors. In FIG. 1, absorbing region 28 is shown as continuous on surface 26. As a variant, absorbing region 28 may be only present between each object 30 and substrate 22 and not be present between objects 30.

The treatment method may comprise the relative displacement between treatment system 10 and object 20 so that laser beam 18 entirely scans the absorbing region 28 to be treated. During the treatment, the optical axis D of optical device 14 is preferably perpendicular to surface 24.

The wavelength of the laser is selected according to the material forming substrate 22 so that substrate 22 is transparent for the laser.

According to an embodiment, particularly when substrate 22 is semiconductor, the wavelength of laser beam 18 is greater than the wavelength corresponding to the bandgap of the material forming substrate 22, preferably by at least 500 nm, more preferably by at least 700 nm. This advantageously enables to decrease interactions between laser beam 18 and substrate 22 during the crossing of substrate 22 by laser beam 18. According to an embodiment, the wavelength of laser beam 18 is smaller than the sum of 2,500 nm and of the wavelength corresponding to the bandgap of the material forming substrate 22. This advantageously enables to be able to more easily supply a laser beam forming a laser spot of small dimensions.

In the case where substrate 22 is semiconductor, the wavelength of laser beam 18 may be in the range from 200 nm to 10 μm. In particular, in the case where substrate 22 is made of silicon which has a 1.14-eV bandgap, which corresponds to a 1.1-μm wavelength, the wavelength of laser beam 18 is selected to be equal to approximately 2 μm. In the case where substrate 22 is made of germanium which has a 0.661-eV bandgap, which corresponds to a 1.87-μm wavelength, the wavelength of laser beam 18 is selected to be equal to approximately 2 μm or 2.35 μm.

In the case where substrate 22 is made of sapphire, the wavelength of laser beam 18 may be in the range from 300 nm to 5 μm.

According to an embodiment, laser beam 18 is polarized. According to an embodiment, laser beam 18 is polarized according to a rectilinear polarization. This advantageously enables to improve the interactions of laser beam 28 with absorbing region 28. According to another embodiment, laser beam 18 is polarized according to a circular polarization. This advantageously enables to favor the propagation of laser beam 18 in substrate 22.

According to an embodiment, laser beam 18 is emitted by treatment system 10 in the form of one pulse, of two pulses, or more than two pulses, each pulse having a duration in the range from 0.1 ps to 1,000 ns. The peak power of the laser beam for each pulse is in the range from 10 kW to 100 MW.

FIG. 2 is an enlarged view of an embodiment of the absorbing region 28 of device 20. According to the present embodiment, absorbing region 28 corresponds to the stacking of a photonic crystal layer 40 and of a layer 42 absorbing for the laser. According to an embodiment, photonic crystal layer 40 is interposed between surface 26 of substrate 22 and absorbing layer 42. As a variant, absorbing layer 42 is interposed between surface 26 of substrate 22 and photonic crystal layer 40. According to an embodiment, a propagation mode of photonic crystal layer 40 corresponds to the wavelength of the laser. Preferably, photonic crystal layer 40 corresponds to a two-dimensional photonic crystal.

According to an embodiment, the thickness of absorbing layer 42 is in the range from 5 nm to 80 nm. The absorption of absorbing layer 42 for the laser is greater than 80%. According to an embodiment, absorbing layer 42 is made of a metal nitride, a semiconductor material, or a mixture of at least two of these compounds. According to an embodiment, the absorption coefficient k of absorbing layer 42 in the linear state for the laser wavelength is in the range from 1 to 10.

Photonic crystal layer 40 comprises a layer 44, called base layer hereafter, of a first material having a first refraction index at the wavelength of the laser where pillars 46 of a second material having a second refraction index at the wavelength of the laser extend. According to an embodiment, each pillar 46 extends substantially along a central axis perpendicular to surface 26 along a height L, measured perpendicularly to surface 26. Call “a” (pitch) the distance between the central axes of two adjacent pillars. According to an embodiment, each pillar 46 extends substantially across the entire thickness of base layer 44. Preferably, the first refraction index is smaller than the second refraction index. The first material may have an absorption coefficient smaller than 1 at the wavelength of laser 18. The first material may be a nitride or an oxide of a semiconductor compound such as silicon oxide (SiO₂), silicon nitride (SiN), or aluminum oxide (A1₂O₃). The second material may have an absorption coefficient smaller than 1 at the wavelength of the laser. The second material may be a nitride of a semiconductor compound, such as GaN, or a semiconductor compound, such as silicon (Si) or germanium (Ge). The thickness of photonic crystal layer 40 may be in the range from 0.1 μm to 3 μm.

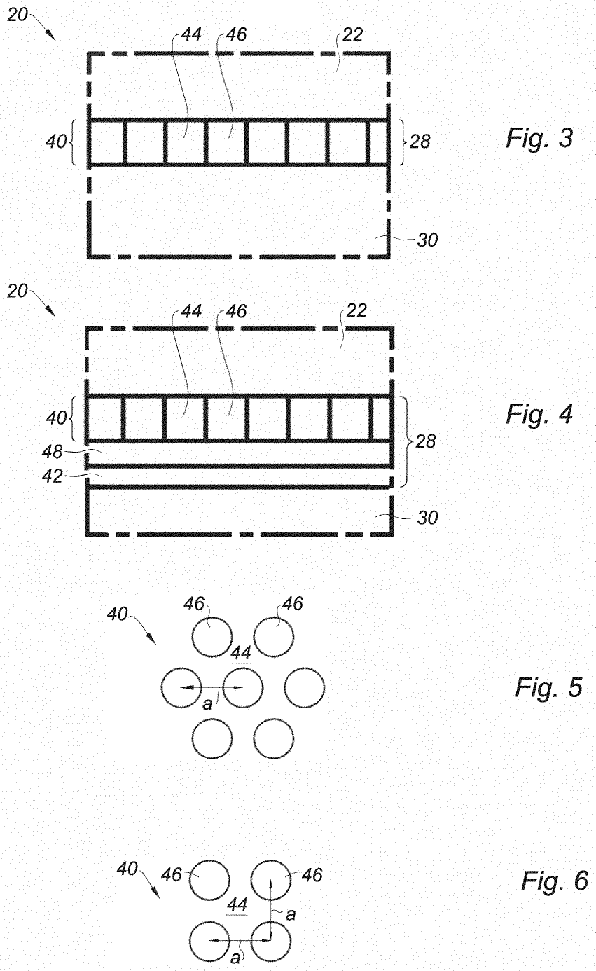

FIG. 3 is an enlarged view of another embodiment of the absorbing region 28 of device 20. Absorbing region 28 comprises all the elements previously described for the embodiment illustrated in FIG. 1, with the difference that absorbing layer 42 is not present. The pillars 46 of photonic crystal layer 40 may be made of one of the materials previously described for absorbing layer 42. In this case, pillars 46 further play the role of absorbing layer 42 as will be described in further detail hereafter. As a variant, the base layer 44 of photonic crystal layer 40 is made of one of the materials previously described for absorbing layer 42. In this case, base layer 44 further plays the role of absorbing layer 42 as will be described in further detail hereafter.

FIG. 4 is an enlarged view of another embodiment of the absorbing region 28 of device 20. Absorbing region 28 comprises all the elements previously described for the embodiment illustrated in FIG. 1, with the difference that it further comprises at least one intermediate layer 48 interposed between photonic crystal layer 40 and absorbing layer 42. Intermediate 48 is transparent for the laser. According to an embodiment, intermediate layer 48 is made of a semiconductor material, for example, made of silicon (Si), of an oxide of a semiconductor, for example, of silicon oxide (SiO₂), or of a nitride of a semiconductor, for example, of silicon nitride (SiN). According to an embodiment, the thickness of intermediate layer 48 is in the range from 1 nm to 500 nm, preferably from 5 nm to 500 nm. As a variant, a stack of two layers or of more than two layers may be interposed between photonic crystal layer 40 and absorbing layer 42. In this case, each layer of the stack is transparent for the laser. According to an embodiment, the total thickness of the stack is in the range from 1 nm to 500 nm, preferably from 5 nm to 500 nm.

According to another embodiment of absorbing region 28, absorbing region 42 is not present and neither the material forming the pillars 46 of photonic crystal layer 40, nor the material forming the base layer 44 of photonic crystal layer 40 has an absorption coefficient k in the range from 1 to 10 at the wavelength of the laser in linear mode.

In the previously-described embodiments of absorbing region 28, the height L of each pillar 46 may be in the range from 0.1 μm to 3 μm. Preferably, pillars 46 are arranged in a grating. According to an embodiment, the pitch a between each pillar 46 and the closest pillar(s) is substantially constant.

FIG. 5 is a partial simplified enlarged top view of an embodiment of photonic crystal layer 40 where pillars 46 are arranged in a hexagonal grating. This means that pillars 46 are, in the top view, arranged in rows, the centers of pillars 46 being at the apexes of equilateral triangles, the centers of two adjacent pillars 46 of a same row being separated by pitch a and the centers of the pillars 46 of two adjacent rows being shifted by distance a/2 along the row direction.

FIG. 6 is an enlarged partial simplified top view of an embodiment of photonic crystal layer 40 where pillars 46 are arranged in a square grating. This means that pillars 46 are arranged in rows and in columns, the centers of pillars 46 being at the tops of squares, two adjacent pillars 46 of a same row being separated by pitch a and two adjacent pillars 46 of a same column being separated by pitch a.

In the embodiments illustrated in FIGS. 5 and 6, each pillar 46 has a circular cross-section of diameter D in a plane parallel to surface 26. In the case of a hexagonal grating arrangement or a square grating arrangement, diameter D may be in the range from 0.05 μm to 2 μm. Pitch a may be in the range from 0.1 μm to 4 μm.

In the embodiments illustrated in FIGS. 5 and 6, the cross-section of each pillar 46 in a plane parallel to surface 26 is circular. The cross-section of pillars 46 may however have a different shape, for example, the shape of an oval, of a polygon, particularly of a square, of a rectangle, of a hexagon, etc. According to an embodiment, all pillars 46 have the same cross-section.

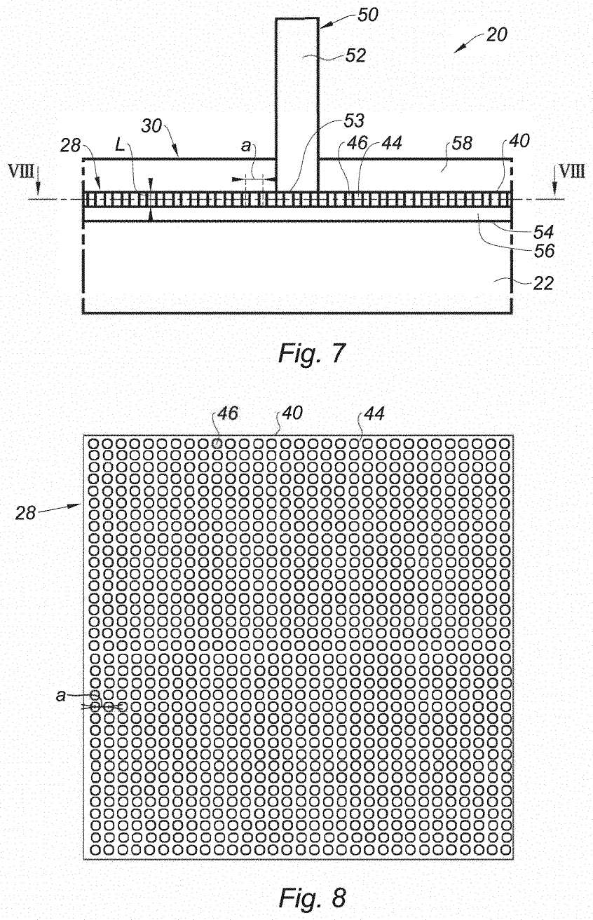

FIG. 7 is an enlarged cross-section view of another embodiment of device 20 and FIG. 8 is a top view with a cross-section of FIG. 7 along plane VIII-VIII. The device 20 shown in FIG. 7 comprises all the elements of the device 20 shown in FIG. 3. Further, in the present embodiment, each object 30 corresponds to an optoelectronic circuit comprising at least one three-dimensional optoelectronic component 50, a single three-dimensional optoelectronic component 50 being shown in FIG. 7. Three-dimensional optoelectronic component 50 comprises a wire, and the other elements of three-dimensional optoelectronic component 50 are not shown in FIG. 7 and are described in further detail hereafter. The base 53 of each wire 52 rests on at least one of pillars 46, preferably on a plurality of pillars 46.

Device 20 further comprises a seed structure 54 favoring the growth of wires 52 and covering substrate 22. Seed structure 54 comprises certain pads 46 of photonic crystal layer 40 and may comprise an additional seed layer or a stack of additional layers. The seed structure 54 shown as an example in FIG. 7 particularly comprises a seed layer 56, layer 56 being interposed between substrate 22 and photonic crystal layer 40.

According to an embodiment, the base layer 44 of photonic crystal layer 40 is made of one of the materials previously described for absorbing layer 42. In the present embodiment, the laser absorption is performed at the level of photonic crystal layer 40 by mechanisms described in further detail hereafter.

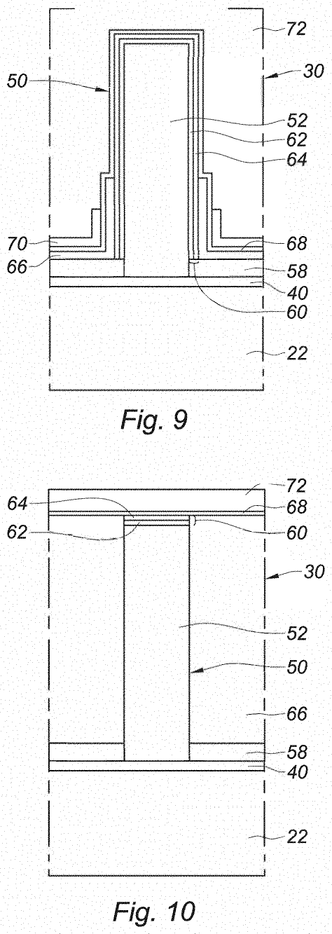

More detailed embodiments of an optoelectronic component 50 of object 30 will be described in relation with FIGS. 9 and 10 in the case where optoelectronic component 50 corresponds to a light-emitting diode of three-dimensional type. It should however be clear that these embodiments may concern other applications, particularly optoelectronic components dedicated to the detection or the measurement of an electromagnetic radiation or optoelectronic components dedicated to photovoltaic applications.

FIG. 9 is a partial simplified cross-section view of an embodiment of an optoelectronic component 50 of optoelectronic circuit 30. Optoelectronic component 30 further comprises an insulating layer 58 covering photonic crystal layer 40.

Three-dimensional optoelectronic component 50 comprises wire 52 projecting from photonic crystal layer 40, schematically shown in FIGS. 9 and 10. Optoelectronic component 50 further comprises a shell 60 covering the external wall of the upper portion of wire 52, shell 60 comprising at least one stack of an active layer 62 covering an upper portion of wire 52 and of a semiconductor layer 64 covering active layer 62. In the present embodiment, optoelectronic component 50 is said to be in radial configuration since shell 60 covers the lateral walls of wire 52. Optoelectronic circuit 30 further comprises an insulating layer 66 which extends over insulating layer 58 and on the lateral walls of a lower portion of shell 60. Optoelectronic circuit 30 further comprises a conductive layer 68 covering shell 60 and forming an electrode, conductive layer 66 being transparent to the radiation emitted by active layer 62. Conductive layer 68 may in particular cover the shells 60 of a plurality of the optoelectronic components 50 of optoelectronic circuit 30, then forming an electrode common to a plurality of electronic components 50. Optoelectronic circuit 30 further comprises a conductive layer 70 extending over electrode layer 68 between wires 52. Optoelectronic circuit 30 further comprises an encapsulation layer 72 covering optoelectronic components 50.

FIG. 10 is a partial simplified cross-section view of another embodiment of optoelectronic component 50. The optoelectronic component 50 shown in FIG. 10 comprises all the elements of the optoelectronic component 50 shown in FIG. 9, with the difference that shell 60 is only present at the top of wire 52. Optoelectronic component 50 is then said to be in axial configuration.

According to an embodiment, wires 52 are at least partly made up of at least one semiconductor material. The semiconductor material is selected from the group comprising III-V compounds, II-VI compounds, or group-IV semiconductors or compounds. Wires 52 may be at least partly made up of semiconductor materials mainly comprising a III-V compound, for example, a III-N compound. Examples of group-III elements comprise gallium (Ga), indium (In), or aluminum (Al). Examples of III-N compounds are GaN, AN, InN, InGaN, AlGaN, or AlInGaN. Other group-V elements may also be used, for example, phosphorus or arsenic. Wires 52 may be at least partly made up of semiconductor materials mainly comprising a II-VI compound. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (0) and tellurium (Te). Examples of II-VI compounds are ZnO, ZnMg0, CdZnO, CdZnMg0, CdHgTe, CdTe, or HgTe. Generally, the elements in the III-V or II-VI compound may be combined with different molar fractions. Wires 52 may be at least partly made up of semiconductor materials mainly comprising at least one group-IV compound. Examples of group-IV semiconductor materials are silicon (Si), carbon (C), germanium (Ge), silicon carbide alloys (SiC), silicon-germanium alloys (SiGe), or germanium carbide alloys (GeC). Wires 52 may comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C), or an N-type group-IV dopant, for example, silicon (Si), germanium (Ge), selenium (Se), sulfur (S), terbium (Tb), or tin (Sn).

Seed structure 54 is made of a material favoring the growth of wires 52. As an example, the material forming pads 46 may be a nitride, a carbide, or a boride of a transition metal from column IV, V, or VI of the periodic table of elements, or a combination of these compounds. As an example, each pad 46 may be made of aluminum nitride (A1N), of aluminum oxide (A1203), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB2), of zirconium nitride (ZrN), of silicon carbide (SiC), of tantalum carbide nitride (TaCN), of magnesium nitride in MgₓN_{y} form, where x is approximately equal to 3 and y is approximately equal to 2, for example, magnesium nitride in Mg₃N₂ form.

Each insulating layer 58, 66 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond.

Active layer 62 may comprise confinement means, such as a single quantum well or multiple quantum wells. It is for example formed of an alternation of GaN and InGaN layers having respective thicknesses from 5 to 20 nm (for example, 8 nm) and from 1 to 10 nm (for example, 2.5 nm). The GaN layers may for example be N- or P-type doped. According to another example, the active layer may comprise a single InGaN layer, for example having a thickness greater than 10 nm.

Semiconductor layer 64, for example, P-type doped, may correspond to a stack of semiconductor layers and allows the forming of a P-N or P-I-N junction, active layer 62 being comprised between the intermediate P-type layer and the N-type wire 52 of the P-N or P-I-N junction.

Electrode layer 68 is capable of polarizing the active layer of the light-emitting diode and of letting through the electromagnetic radiation emitted by the light-emitting diode. The material forming electrode layer 68 may be a transparent conductive material such as indium tin oxide (or ITO), pure zinc oxide, aluminum zinc oxide, gallium zinc oxide, graphene, or silver nanowires. As an example, electrode layer 68 has a thickness in the range from 5 nm to 200 nm, preferably from 30 nm to 100 nm.

Encapsulation layer 72 may be made of an organic material or an inorganic material and is at least partially transparent to the radiation emitted by the light-emitting diode. Encapsulation layer 72 may comprise luminophores capable, when they are excited by the light emitted by the light-emitting diode, of emitting light at a wavelength different from the wavelength of the light emitted by the light-emitting diode.

First simulations have been performed. For these first simulations, photonic crystal layer 40 comprises pillars 46 made of Si and base layer 44 was made of SiO₂. Pillars 46 were distributed in a hexagonal grating, each pillar 46 having a circular cross-section with a diameter D equal to 0.97 μm. For the first simulations, the thickness L of pillars 46 was equal to 1 μm. Absorbing layer 42 had a 50-nm thickness, a refraction index equal to 4.5, and an absorption coefficient equal to 3.75.

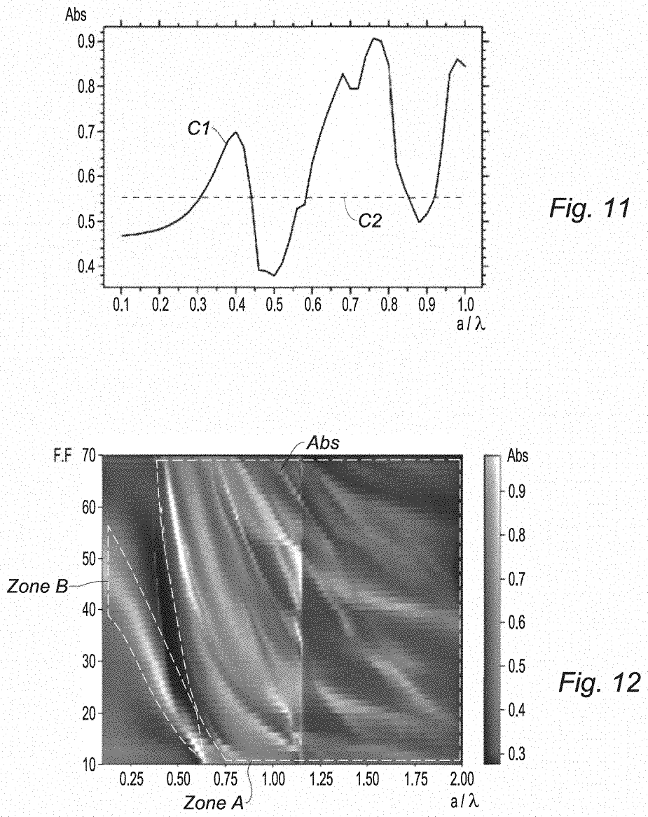

FIG. 11 shows curves C1 and C2 of variation of the average absorption Abs of absorbing region 28 according to the ratio a/λ of pitch a to the wavelength λ of the laser, curve Cl being obtained when region 28 has the structure shown in FIG. 4 and curve C2 being obtained when region 28 does not comprise photonic crystal layer 40 but only absorbing layer 42. In the absence of photonic crystal layer 40, the average absorption in absorbing region 28 is approximately 55%. In the presence of photonic crystal layer 40, the average absorption exceeds 55% over a plurality of ranges of ratio a/λ and even reaches 90% when ratio a/λ is equal to approximately 0.75.

Second simulations have been performed. For these second simulations, photonic crystal layer 40 comprised pillars 46 made of Si and base layer 44 was made of SiO₂. Pillars 46 were distributed in a hexagonal grating, each pillar 46 having a circular cross-section. For the second simulations, the thickness L of pillars 46 was equal to 1 μm.

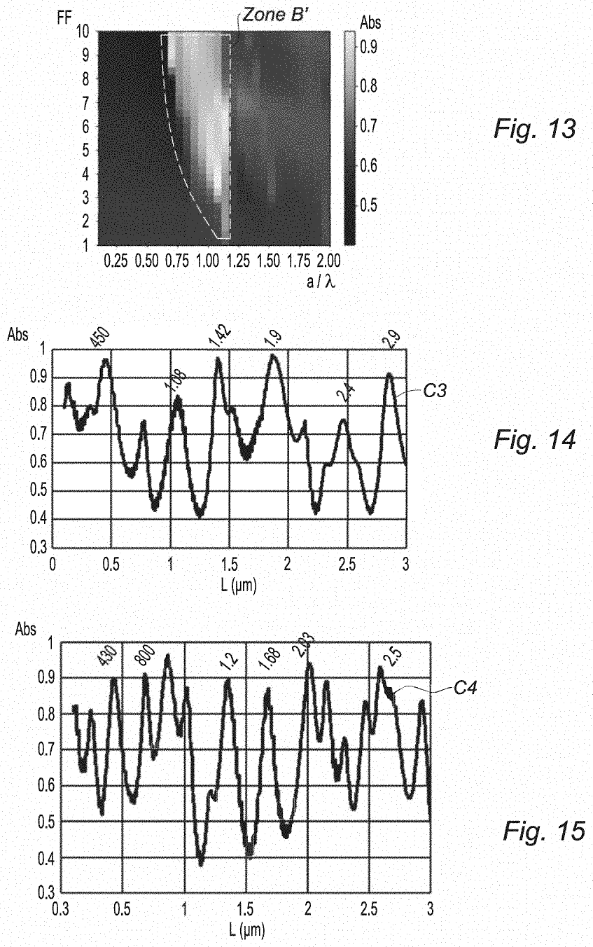

FIGS. 12 and 13 each show a depth map, in grayscale, of the average absorption Abs in absorbing region 28 according to ratio a/λ in abscissas and to filling factor FF in ordinates. Filling factor FF corresponds to the ratio, in top view, of the sum of the areas of pillars 46 to the total area of photonic crystal layer 40. As an example, for pillars 46 having a circular cross-section, filling factor FF is provided by the following relation [Math 1]:

$$FF = \frac{{3}^{*} {( \frac{D}{2} )}^{2}}{{a}^{2}} \qquad [ Math 1 ]$$

One can distinguish an area A and an area B in FIG. 12 and an area B′ in FIG. 13 for which the average absorption Abs is greater than approximately 70%. Areas B and B′ are obtained for a ratio a/λ in the range from 0.1 to 1 and a filling factor FF in the range from 1% to 50% and area A is obtained for a ratio a/λ in the range from 0.5 to 2 and a filling factor FF in the range from 10% to 70%.

FIG. 14 shows a curve C3 of the variation of the average absorption Abs according to the height L of pillars 46 for a filling factor FF equal to 0.3 and for a ratio a/λ equal to 0.6.

FIG. 15 shows a curve C4 of the variation of the average absorption Abs according to the height L of pillars 46 for a filling factor FF equal to 0.5 and for a ratio a/λ equal to 0.6.

Curves C3 and C4 exhibit local maximum values which correspond to Fabry-Perot resonances at different orders, the corresponding values of height L being indicated in FIGS. 14 and 15. It is preferable to select the height L of pillars 46 to be substantially at the level of one of the Fabry Perot resonances.

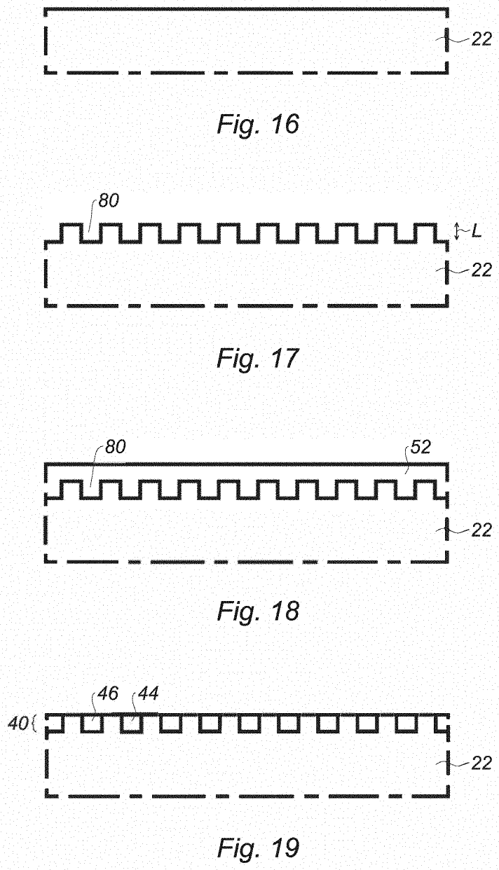

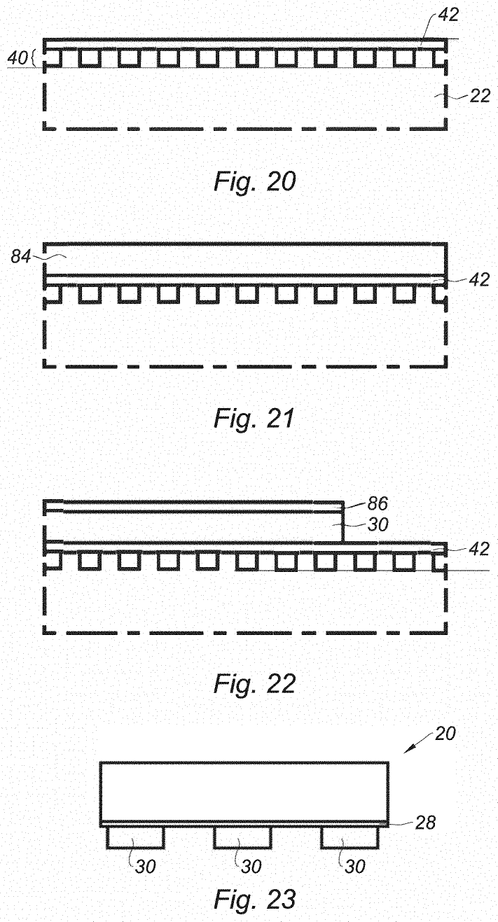

FIGS. 16 to 22 are partial simplified cross-section views of the structures obtained at successive steps of a method of manufacturing device 20 for which absorbing region 28 has the structure shown in FIG. 2. The manufacturing method comprises the following steps:
manufacturing of substrate 22 (FIG. 16);
etching, in substrate 22, of openings 80 down to a depth substantially equal to the desired height L, the cross-section of openings 80 corresponding to the desired cross-section of pillars 46 (FIG. 17);
deposition of a layer 82 of the second material covering substrate 22 and particularly filling openings 80 (FIG. 18);
etching of layer 82 to reach substrate 22, for example, by chemical-mechanical planarization (CMP), to only keep the portions of layer 82 in openings 80 which form the pillars 46 of photonic crystal layer 40, the portion of substrate 22 surrounding pillars 46 forming the base layer 44 of photonic crystal layer 40 (FIG. 19);
deposition or growth of absorbing layer 42 on photonic crystal layer 40 (FIG. 20);
forming of a stack of layers 84 on absorbing layer 42 (FIG. 21); and
etching of layer stack 84 down to absorbing layer 42 to delimit objects 30 (FIG. 22), a single object being partially shown in FIG. 22, for example, by using an etch mask 86.

FIGS. 23 to 26 are partial simplified cross-section views of the structures obtained at successive steps of another embodiment of a laser treatment method of device 20.

FIG. 23 shows the structure obtained after the manufacturing of device 20.

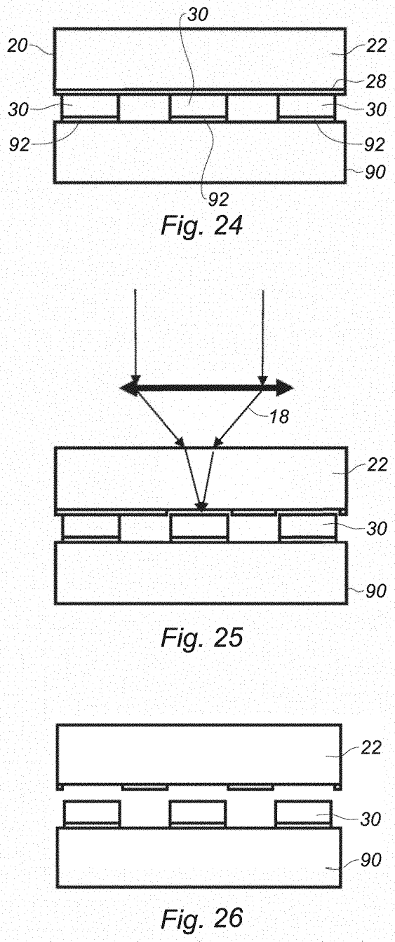

FIG. 24 shows the structure obtained after the placing of device 20 into contact with a support 90 causing the bonding of objects 30 to support 90. According to an embodiment, the bonding of objects 30 to support 90 may be obtained by hybrid molecular bonding of the objects to support 90. According to an embodiment, support 90 may comprise pads 92 at the bonding locations of objects 30. Device 20 and support 90 are then brought towards each other until objects 30 come into contact with pads 92. According to an embodiment, not all the objects 30 bonded to support 22 are intended to be transferred onto a same support 90. For this purpose, support 90 may comprise pads 92 only for the objects 30 to be transferred onto support 90. In this case, when device 20 and support 90 are brought towards each other until some of the objects 30 come into contact with pads 92, the objects 30 which are not in front of a pad 92 are not in contact with support 90 and are thus not bonded to support 90.

FIG. 25 shows the structure obtained during the passage of laser 18 to detach from substrate 22 the objects 30 to be transferred onto support 90. In operation, laser beam 18 is preferably focused onto absorbing region 28. The photonic crystal layer 40 of absorbing region 28 enables to increase the absorption of the laser light by absorbing region 28.

When absorbing region 28 comprises absorbing layer 42, photonic crystal layer 40 enables in particular to increase the absorption of the light of laser 18 in absorbing layer 42. This enables to obtain the ablation of absorbing layer 42. When pillars 46 or base layer 44 is made of a material absorbing laser 18, photonic crystal layer 40 enables in particular to increase the absorption of the laser light in pillars 46 or in base layer 44. This enables to obtain the ablation of photonic crystal layer 40.

When absorbing layer 42 is not present, and neither the material forming the pillars 46 of photonic crystal layer 40, nor the material forming the base layer 44 of photonic crystal layer 40 has an absorption coefficient k in the range from 1 to 10 at the wavelength of the laser in linear mode, photonic crystal layer 40 enables to locally increase the density of energy in photonic crystal layer 40 and in the vicinity of photonic crystal layer 40. This enables to increase the absorption of the laser by non-linear absorption phenomena in photonic crystal layer 40 and in the vicinity of photonic crystal layer 40, particularly in substrate 22, which causes the ablation of photonic crystal layer 40. The presence of photonic crystal layer 40 then enables to decrease the intensity of the laser for which the non-linear absorption phenomena appear in photonic crystal layer 40 and/or in the vicinity of photonic crystal layer 40, particularly in substrate 22.

When substrate 22 is made of a semiconductor material, particularly silicon, it may be necessary for the laser wavelength to be in the infrared band, so that substrate 22 is transparent to the laser. However, commercially-available infrared lasers generally have a lower maximum energy than other commercially-available lasers at other frequencies. The use of photonic crystal layer 40 advantageously enables to perform a laser cutting even with an infrared laser, and thus advantageously enables to use a semiconductor substrate 22, in particular, made of silicon

FIG. 26 shows the structure obtained after the drawing away of substrate 22 from support 90. The objects 30 bonded to support 90 are detached from substrate 22.

In the previously-described embodiments, pillars 46 are distributed in a regular grating. According to another embodiment, the grating of pillars 46 may comprise defects to modify the distribution of the density of energy in photonic crystal layer 40 and/or in the vicinity of photonic crystal layer 40. A defect may in particular correspond to the absence of a pillar 46 in the grating of pillars 46 or to the presence of a pillar 46 having dimensions different than those of the adjacent pillars, for example, having a diameter D different from the diameter of the adjacent pillars in the case of pillars having a circular cross-section.

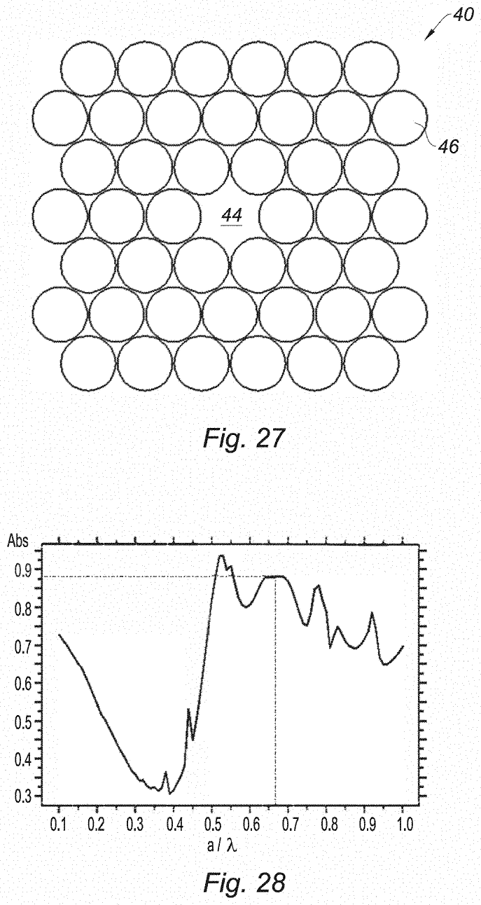

FIG. 27 is a top view similar to FIG. 5 where a pillar 46 is missing in the grating of pillars 46.

FIG. 28 is a top view similar to FIG. 7 obtained with the arrangement shown in FIG. 27. An average absorbance Abs greater than 90% is obtained for a ratio a/λ approximately equal to 0.53.

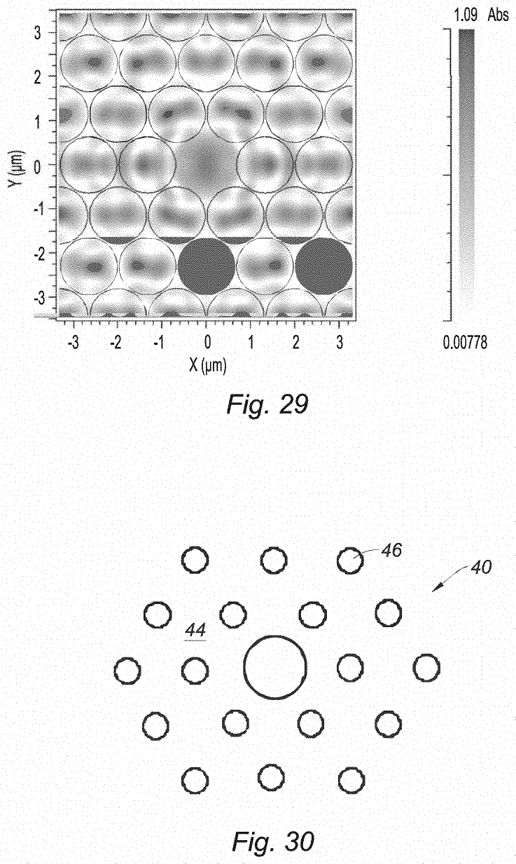

FIG. 29 is a grayscale depth map showing the density of energy obtained in a plane located in photonic crystal layer 40, parallel to surface 26, and separated from surface 26 by 0.6 μm, with the arrangement shown in FIG. 27 when ratio a/λ is equal to approximately 0.66 with a 0.7 filling factor. As shown in FIG. 29, a local increase of the density of energy is obtained at the location of the missing pillar. This enables, even for an average absorption, to locate the maximum values of energy density peaks. According to an embodiment, the defects of the grating of the photonic crystal layer are distributed so that the maximum values of the energy peaks are located at the level of the objects 30 to be transferred. This enables to obtain energy density peaks at accurate positions, even if the positioning of laser 18 is performed less accurately. The presence of defects enables to position the areas where the absorption is the highest at desired locations.

FIG. 30 is a top view similar to FIG. 5 where a pillar 46 has a larger diameter than the other pillars in the array of pillars of photonic crystal layer 40. According to parameters a and D, the energy density distribution may have a general shape similar to that of FIG. 29.

Various embodiments and variants have been described. Those skilled in the art will understand that certain features of these various embodiments and variants may be combined, and other variants will occur to those skilled in the art. Finally, the practical implementation of the described embodiments and variants is within the abilities of those skilled in the art based on the functional indications given hereabove.

1. Device configured for a treatment with a laser comprising a substrate transparent for the laser and objects, each object being bonded to the substrate via a photonic crystal.

2. Device according to claim 1, wherein the photonic crystal is a two-dimensional photonic crystal.

3. Device according to claim 1, wherein the photonic crystal comprises a base layer of a first material and a grating of pillars of a second material different from the first material, each pillar extending in the base layer across at least a portion of the thickness of the base layer.

4. Device according to claim 3, wherein the first material has an absorption coefficient for the laser smaller than 1.

5. Device according to claims 1, wherein the second material has an absorption coefficient for the laser smaller than 1.

6. Device according to claim 5, wherein the substrate is formed of said second material.

7. Device according to claim 1, wherein the second material has an absorption coefficient for the laser in the range from 1 to 10.

8. Device according to claim 1, wherein the substrate comprises first and second opposite surfaces, the laser being intended to cross the substrate from the first surface to the second surface, the photonic crystal covering the second surface.

9. Device according to claim 1, further comprising a layer absorbing for the laser between the objects and the substrate.

10. Device according to claim 9, further comprising at least one layer transparent for the laser, interposed between the photonic crystal and the layer absorbing for the laser.

11. Device according to claim 1, wherein the substrate is semiconductor.

12. Device according to claim 11, wherein the substrate is made of silicon, of germanium, or of a mixture or an alloy of at least two of these compounds.

13. Device according to claim 1, wherein the object comprises an electronic circuit.

14. Device according to claim 3, wherein the object comprises at least one optoelectronic component having a three-dimensional semiconductor element covered with an active layer, the three-dimensional semiconductor element comprising a base in contact with at least one of the pillars.

15. Device according to claim 14, wherein the second material is a nitride, a carbide, or a boride of a transition metal from column IV, V, or VI of the periodic table of elements or a combination of these compounds or wherein the second material is aluminum nitride, aluminum oxide, boron, boron nitride, titanium, titanium nitride, tantalum, tantalum nitride, hafnium, hafnium nitride, niobium, niobium nitride, zirconium, zirconium borate, zirconium nitride, silicon carbide, tantalum carbonitride, magnesium nitride, or a mixture of at least two of these compounds.

16. Method of manufacturing a device comprising a substrate transparent for the laser and objects, each object being bonded to the substrate via a photonic crystal, the method comprising the forming of the photonic crystal and the forming of the object.

17. Method according to claim 16, comprising the forming of the photonic crystal on the substrate and the forming of the object on the photonic crystal comprising steps of deposition and/or of growth of layers on the photonic crystal.

18. Method of treatment with a laser of a device comprising a substrate transparent for the laser and objects, each object being bonded to the substrate via a photonic crystal, the method comprising exposing the photonic crystal to the laser beam through the substrate.

19. Method according to claim 18, comprising the bonding of the object to a support, the object being still coupled to the substrate and the destruction of a region comprising the photonic crystal or adjacent to the photonic crystal by the laser.
